(19) United States
(12) Patent Application Publication
(10) Pub. No.: US 2022/0246836 A1
(43) Pub. Date: Aug. 4, 2022

(54) COMPOSITE RECORDING STRUCTURE FOR AN IMPROVED WRITE PROFERMANCE

(71) Applicants: YIMIN GUO, SAN JOSE, CA (US); RONGFU XIAO, DUBLIN, CA (US); JUN CHEN, Fremont, CA (US)

(72) Inventors: YIMIN GUO, SAN JOSE, CA (US); RONGFU XIAO, DUBLIN, CA (US); JUN CHEN, Fremont, CA (US)

(21) Appl. No.: 17/165,105

(22) Filed: Feb. 2, 2021

(51) Int. Cl. H01L 43/02; H01L 27/22; H01L 43/10

(52) U.S. Cl. CPC H01L 43/02; H01L 43/10; H01L 27/222

(57) ABSTRACT

A composite recording structure comprising a first magnetic free layer comprising an amorphous magnetic material sub-layer, a Boron-absorbing material sub-layer atop the amorphous magnetic material sub-layer and a Co/Ni superlattice sub-layer atop the Boron-absorbing material sub-layer; one or many repeats of a substructure including a nonmagnetic spacing layer and a Co/Ni superlattice free layer, atop the first magnetic free layer, wherein said first magnetic free layer has a perpendicular magnetic anisotropy and a variable magnetization direction substantially perpendicular to a film surface, said each Co/Ni superlattice free layer has a perpendicular magnetic anisotropy and a variable magnetization direction substantially perpendicular to a film surface.

### CROSS-REFERENCE TO RELATED APPLICATIONS

This application is related to U.S. patent application Ser. No. 17/160,349 entitled MAGNETORESISTIVE ELEMENT HAVING A COMPOSITE RECORDING STRUCTURE, filed Jan. 27, 2021, and incorporated herein by reference.

### BACKGROUND OF THE INVENTION

### 1. Field of the Invention

This invention relates to the field of magnetoresistive elements. More specifically, the invention comprises magnetic-random-access memory (MRAM) using magnetoresistive elements with composite recording structures having additional Ni-containing magnetic free layers for fast writing and low powers as basic memory cells which potentially replace the conventional semiconductor memory used in electronic chips, especially mobile chips for power saving and non-volatility as well as memory blocks in processor-in-memory (PIM).

### 2. Description of the Related Art

In recent years, magnetic random access memories (hereinafter referred to as MRAMs) using the magnetoresistive effect of ferromagnetic tunnel junctions (also called MTJs) have been drawing increasing attention as the next-generation solid-state nonvolatile memories that can cope with high-speed reading and writing, large capacities, and low-power-consumption operations. A ferromagnetic tunnel junction has a three-layer stack structure formed by stacking a recording layer having a changeable magnetization direction, an insulating spacing layer (also called a tunnel barrier layer), and a fixed reference layer that is located on the opposite side from the recording layer and maintains a predetermined magnetization direction. The change of electrical resistance of the MTJ device is attributed to the difference in the tunneling probability of the spin polarized electrons through the tunnel barrier on the bias voltage across the device in accordance with the relative orientation of magnetizations of the ferromagnetic recording layer and the ferromagnetic reference layer. The ferromagnetic recording layer is also referred to as a free layer. MR ratio is defined as (R_{AP}-R_{P})/R_{P}, where R_{AP} and R_{P} are resistances in anti-parallel and parallel magnetization at zero-magnetic field, respectively.

Further, as in a so-called perpendicular MTJ element, both two magnetization films of the recording layer and the reference layer have easy axes of magnetization in a direction perpendicular to the film plane due to their strong perpendicular magnetic anisotropies (PMA) induced by both interfacial interaction and/or crystalline structure (shape anisotropies are not used), and accordingly, the device size can be made smaller than that of an in-plane magnetization type. Also, the variance in the easy axis of magnetization can be made smaller. Accordingly, by using a material having a large perpendicular magnetic anisotropy, both miniaturization and lower currents can be expected to be achieved while a thermal disturbance resistance is maintained.

There has been a known technique for achieving a high MR ratio and a high PMA in an MTJ element by forming an underneath MgO tunnel barrier layer and an MgO cap layer that sandwich a recording layer having a pair of amorphous CoFeB ferromagnetic sub-layers, i.e., the first free sub-layer (FL1) and the second free sub-layer (FL2), and a Boron-absorbing sub-layer positioned between them, and performing a thermal annealing process to accelerate crystallization of the amorphous ferromagnetic film to match interfacial grain structure to both the MgO tunnel barrier layer and the MgO cap layer. An MgO layer has a rocksalt crystalline structure in which each of Mg and O atoms forms a separate face-centered cubic (FCC) lattice, and Mg and O atoms together form a simple cubic lattice. The Boron-absorbing sub-layer is typically made of Mo or W material. The recording layer crystallization starts from both the MgO tunnel barrier layer interface and the MgO cap layer interface to its center and forms a CoFe grain structure, which is mainly a body-centered cubic (bcc) crystalline structure, having a volume perpendicular magnetic anisotropy (vPMA), as Boron atoms migrate into the Boron-absorbing sub-layer. In the same time, a typical bcc-CoFe(100)/rocksalt-MgO(100) texture occurs at the interface between a CoFeB sub-layer and an MgO layer. At two MgO interfaces, the orbital hybridization between cobalt 3dz2 and oxygen 2p orbitals significantly lowers the energy of the Co—O bonds, which leads to an interfacial perpendicular magnetic anisotropy. This is the same for a CoFeB reference layer underneath the MgO tunnel barrier layer. Accordingly, a coherent perpendicular magnetic tunneling junction structure is formed as an unique structure: bcc-CoFe(reference-layer)/rocksalt-MgO/bcc-CoFe/(W-boride or Mo-boride)/bcc-CoFe/rocksalt-MgO after a thermal annealing process. By using this technique, both a high MR ratio and a high PMA can be readily achieved. However, as the operation temperature rises, the PMA decreases rapidly. For an application with a wide operation temperature range, there must be a trade-off between data retention and write power consumption.

It is reported (see Article: Co/Ni Multilayers With Perpendicular Anisotropy For Spintronic Device Applications, APPLIED PHYSICS LETTERS 100, 172411, 2012, by You, et al.) that a strong perpendicular anisotropy can also be obtained in as-deposited and annealed Co/Ni multilayers grown on a Pt buffer layer. However, for a Co/Ni multilayer grown on an MgO buffer layer, a much less perpendicular anisotropy is achieved even after annealing at 250° C. for 30 min. More importantly, a Co/Ni multilayer has an FCC (111) crystalline structure that does not provide the same structure matching to rocksalt-MgO (100) employed in high-TMR MTJs with bcc-CoFe (100), which leads a low MR ratio. For these reasons, Co/Ni multilayers have only been used as a part of a reference structure or a part of a recording structure below the tunnel barrier layer, such as disclosed in U.S. Pat. No. 8,987,847 by G. Jan, et al. and U.S. Patent Publication 2020/0243749A1 by D. Worledge, et al.

Magnetization direction of a free layer is used to store the data and can be switched by spin-polarized electrons (equivalently spin current) without a magnetic field. When the spin-polarized current flows through the free layer along a specific direction, the free layer absorbs spin angular momentum from the electrons and as a result, its magnetization direction is reversed when the magnitude of the current is sufficiently large. Furthermore, as the volume of the magnetic layer forming the free layer is smaller, the injected spin-polarized current to write or switch can be also smaller. Accordingly, this method is expected to be a write method that can achieve both device miniaturization and lower currents. However, for random-access-memory (RAM) like applications, this technology faces various challenges along with its merits, such as the reliability of a tunnel barrier, long write latency and small energy efficiency due to still high write current. In theory, the critical current with a sufficient long pulse needed to reverse the magnetization direction of the free layer is proportional to its damping constant and the energy barrier between R_{AP} and R_{P} states, and furthermore, the critical current rapidly increases with a shorter pulse. Roughly, the increased amount of the critical current is inversely proportional to the product of the damping constant and the effective PMA field (Hk) of the free layer. Since the PMA of the free layer needs to be sufficiently high to maintain a reasonable thermal stability factor (E/k_{B}T, where E is the product of the PMA and volume of the recording layer and also denotes the energy barrier between the two stable magnetization configurations of the recording layer, k_{B} is the Boltzmann constant, and T is the absolute temperature 300K) which is normally required to be larger than 70 in the operation temperature range, the current density for switching of perpendicular spin transfer torque MRAM (pSTT-MRAM) is relatively large and hence large transistors are inevitable to drive it, which thus significantly limits their future use for memory applications. Therefore, it is desired to develop new technologies to greatly reduce the critical current at a short pulse while keeping a high thermal stability factor.

### SUMMARY OF THE PRESENT INVENTION

According to one embodiment of the present invention, a perpendicular magnetoresistive element having a composite recording structure comprises: a reference layer having a magnetic anisotropy in a direction perpendicular to a film surface and having an invariable magnetization direction; a tunnel barrier layer provided on the reference layer; a composite recording structure provided on the tunnel barrier layer and having a first free layer (FL1), a second free layer (FL2) and a nonmagnetic spacing layer positioned between them, wherein the first free layer is a Ni— containing magnetic layer having a magnetic anisotropy in a direction perpendicular to a film surface and having a variable magnetization direction, and the second free layer is a Ni-containing magnetic layer having magnetic anisotropy in a direction perpendicular to a film surface and having a variable magnetization direction; a cap layer on the composite recording structure. Both the first magnetic free layer and the second magnetic free layer have high spin polarization degrees, and their magnetizations are magneto-statically coupled across the nonmagnetic spacing layer but individually switchable by sufficiently large spin transfer torques when an electric current is applied in a specific direction. The FL1 is made of CoFeB/Mo(or other Boron-absorbing materials)/(Co/Ni)n and the nonmagnetic spacing layer is NiCr or NiFeCr. Here and thereafter throughout this application, each element written in the left side of “/” is stacked above an element written in the right side thereof.

The FL2 is made of Co/Ni superlattice, and the cap layer is a metal layer having a FCC crystal structure such as NiCr or a HCP crystal structure such as Ru. After a thermal annealing process, a multilayered structure [Co/Ni]n, where n is a small positive integer, forms a better Co/Ni superlattice for a strong perpendicular magnetic anisotropy. Since both the FL1 and the FL2 contain Ni atoms, they have sufficient high damping constants for a fast STT-driven magnetization reversal.

According to a second embodiment of the present invention, a composite recording structure comprises: two or more magnetic free layers interleaved by nonmagnetic spacing layers, wherein each magnetic free layer has a perpendicular magnetic anisotropy, a magnetic anisotropy energy maximum and a variable magnetization direction substantially perpendicular to a film surface, and each spacing layer has a sufficiently small thickness so that magnetizations of magnetic free layers are magneto-statically coupled and are in a parallel direction substantially perpendicular to a film surface in absent of an external magnetic field and an electric current. Each magnetic anisotropy energy maximum of each magnetic free layer is no more than seventy multiplied by Boltzman's constant multiplied by a temperature of the magnetic junction, but a total sum of magnetic anisotropy energy maximums from all magnetic free layers is larger than seventy multiplied by Boltzman's constant multiplied by a temperature of the magnetic junction.

In this invention, there is further a magnetic STT-enhancing structure provided on the cap layer as another embodiment of the invention. The magnetic STT-enhancing structure comprises: a first magnetic material layer atop the cap layer and having an invariable magnetization direction antiparallel to the magnetization direction of the reference layer, an anti-ferromagnetic coupling (AFC) layer atop the first magnetic material layer and a second magnetic material layer atop the AFC and having an invariable magnetization direction antiparallel to the magnetization direction of the first magnetic material layer. The cap layer is made of a nonmagnetic material having a large spin diffusion length such that the magnetic STT-enhancing structure introduces an additional spin transfer torque assisting the magnetization reversal of the recording layer during a write process.

The present invention comprises methods of manufacturing such perpendicular magnetoresistive elements for perpendicular STT-MRAM devices with high write speeds and low write currents while maintaining high thermal stabilities. The perpendicular magnetoresistive element in the invention is sandwiched between an upper electrode and a lower electrode of each MRAM memory cell, which also comprises a write circuit which bi-directionally supplies a spin polarized current to the magnetoresistive element and a select transistor electrically connected between the magnetoresistive element and the write circuit.

### BRIEF DESCRIPTION OF THE DRAWINGS

FIG. 1 is a cross-sectional view showing a schematic configuration of an MTJ element as a prior art.

FIG. 2 is a cross-sectional view showing a schematic configuration of a composite recording structure having a first magnetic free layer having Co/Ni superlattice, a nonmagnetic spacing layer and a second magnetic free layer of Co/Ni superlattice.

FIG. 3 is a cross-sectional view showing a schematic configuration of a composite recording structure having a first magnetic free layer Co/Ni superlattice, one or more repeats of a substructure including a nonmagnetic spacing layer and a second magnetic free layer of Co/Ni superlattice.

FIG. 4 is a cross-sectional view showing a schematic configuration of a magnetoresistive element having a composite recording layer, a cap layer and a magnetic STT-enhancing structure.

### DETAILED DESCRIPTION OF THE INVENTION

The present application will now be described in greater detail by referring to the following discussion and drawings that accompany the present application. It is noted that the drawings of the present application are provided for illustrative purposes only and, as such, the drawings are not drawn to scale. It is also noted that like and corresponding elements are referred to by like reference numerals.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present. Here, and thereafter throughout this application, each element written in the left side of “/” is stacked above an element written in the right side thereof.

In a first aspect of this invention, there is provided a composite recording structure comprising:

a first free layer having a perpendicular magnetic anisotropy and a variable magnetization direction and including an amorphous magnetic material sub-layer, a Boron-absorbing material sub-layer atop the amorphous magnetic material sub-layer and a Co/Ni superlattice sub-layer atop the Boron-absorbing material sub-layer;

one or more repeats of a substructure atop the first free layer and including a nonmagnetic spacing layer and a second free layer which is made of a Co/Ni superlattice.

In a second aspect of this invention, there is provided a magnetoresistive element comprising:

a reference layer having a perpendicular magnetic anisotropy and having an invariable magnetization direction;

a tunnel barrier layer atop the reference layer;

a composite recording structure atop the tunnel barrier layer;

a cap layer atop the composite recording structure; and

an upper-contact multilayer provided on the most top of above said layers.

In a third aspect of this invention, there is provided a magnetoresistive element comprising:

a reference layer having a perpendicular magnetic anisotropy and having an invariable magnetization direction;

a tunnel barrier layer atop the reference layer;

a composite recording structure atop the tunnel barrier layer;

a cap layer atop the composite recording structure;

a magnetic STT-enhancing structure atop the cap layer and comprising: a first perpendicular magnetic layer atop the cap layer and having a magnetization direction antiparallel to the magnetization direction of the reference layer, an AFC layer atop the first perpendicular magnetic layer and a second perpendicular magnetic layer atop the AFC and having a magnetization direction parallel to the magnetization direction of the reference layer; and

an upper-contact multilayer provided on the most top of above said layers.

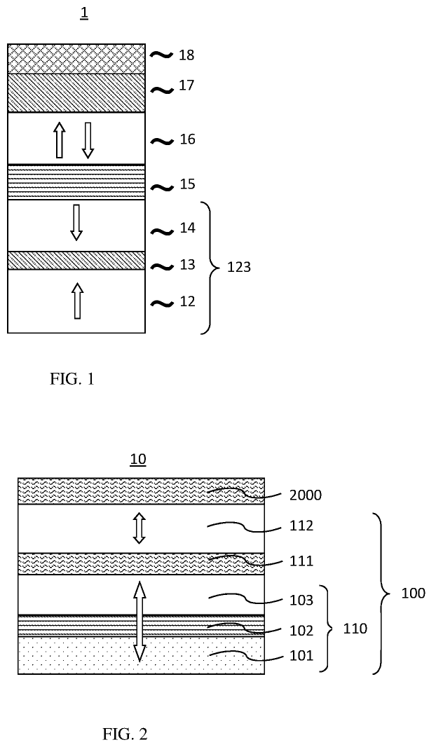

FIG. 1 is a cross-sectional view showing a configuration of an MTJ element 1 as a prior art. The MTJ element 1 is configured by stacking a bottom pinning layer 12, an anti-ferromagnetic coupling (AFC) layer 13, a reference layer 14, a tunnel barrier layer 15, a recording layer 16, a cap layer 17, and a protective layer 18 in this order from the bottom to the top. The bottom pinning layer 12 is typically made of super-lattice multilayer and has a strong perpendicular magnetic anisotropy. The bottom pinning layer 12 and the reference layer 14 are magnetically antiparallel-coupled through the anti-ferromagnetic coupling (AFC) layer 13, forming a reference structure 123. The tunnel barrier layer 15 is made of a non-magnetic insulating metal oxide or nitride. The recording layer 16 is made of ferromagnetic materials and has a magnetic anisotropy in a direction perpendicular to the film surface. The tri-layered structure consisting of the layers 14, 15 and 16 forms a magnetic tunneling junction (MTJ). The recording layer 16 has a variable (reversible) magnetization direction, while the reference layer 14 has an invariable (fixed) magnetization direction. The perpendicular magnetic anisotropic energy of the reference layer 14, partly coming from the antiparallel-coupling with the bottom pinning layer 12, is sufficiently greater than that of the recording layer 16. This strong perpendicular magnetic anisotropy can be achieved by selecting a material, configuration and a film thickness. The perpendicular resistance of the MTJ is high when the magnetizations between the recording layer 16 and the reference layer 14 are anti-parallel; and the perpendicular resistance of the MTJ is low when the magnetizations between the recording layer 16 and the reference layer 14 are parallel. Also in this manner, a spin polarized current may only reverse the magnetization direction of the recording layer 16 while the magnetization direction of the reference layer 14 remains unchanged. The cap layer 17 is a metal oxide layer and serves to introduce an interfacial perpendicular magnetic anisotropy for the recording layer 16. As an amorphous ferromagnetic material, CoFeB, in the recording layer is thermally annealed, a crystallization process occurs to form bcc CoFe grains having epitaxial growth with (100) plane parallel to surface of the tunnel barrier layer. The (100) texture extends across the whole stack from the tunnel barrier layer to the cap layer, producing a desired perpendicular magnetic anisotropy for the recording layer.

### First Embodiment of Current Invention

FIG. 2 is a cross-sectional view showing a configuration of a composite recording structure 1000 and a cap layer 2000 as deposited according to the first embodiment in this invention. The composite recording structure 1000 is configured by stacking a first free layer (FL1) 110, a nonmagnetic spacing layer 111 and a second free layer (FL2) 112, in the order from the bottom to the top. The first free layer consists of an amorphous magnetic material sub-layer 101, a Boron-absorbing material sub-layer 102 atop the amorphous magnetic material sub-layer and a Co/Ni superlattice sub-layer 103 atop the Boron-absorbing material sub-layer. Further, the cap layer 2000 is provided atop the composite recording structure 1000.

The amorphous magnetic material sub-layer 101 is made of CoFeB, CoFeB/Fe, CoB/Fe, CoFe/CoFeB, FeB/CoFe, CoB/CoFe or CoFeB/CoFe. The Boron-absorbing material sub-layer 102 is made of a metal or metal alloy containing at least one element selected from the group of Ta, Hf, Zr, Ti, Mg, Nb, W, Mo, Ru and Al. Both the Co/Ni superlattice sub-layer 103 and the second free layer (FL2) 112 are made of [Co/Ni]n, [Co/Ni]n/Co, [Co/Ni]n/CoFe, Ni/[Co/Ni]n, Ni/[Co/Ni]n/Co or Ni/[Co/Ni]n/CoFe, where n is a positive integer. Both the nonmagnetic spacing layer 111 and the cap layer are made of a metal or metal alloy of transition metal or transition metal alloy having a face-centered cubic (FCC) crystal structure or a hexagonal close-packed (HCP) crystal structure, such as NiCr, NiFeCr and Ru.

As a thermal annealing process is applied to the composite recording structure, Boron elements inside the amorphous magnetic material sub-layer migrate to the Boron-absorbing material sub-layer, and a crystallization process of the amorphous magnetic material sub-layer occurs to form body-centered cubic (bcc) CoFe grains having an epitaxial growth, especially a bcc-CoFe (100)/MgO (100) texture with an underneath MgO tunnel barrier layer. This crystal texture is essential for achieving a high MR ratio. The Boron-absorbing material sub-layer further serves as a crystal breaking layer which separates the crystalline structures between the amorphous magnetic material sub-layer and the Co/Ni superlattice sub-layer. Also after the thermal annealing, the face-centered cubic (FCC) (111) textures of the Co/Ni superlattice sub-layer and the FL2 are further improved and leads to perpendicular magnetic anisotropies for both the first free layer and the second free layer. In another word, both of the FL1 and FL2 have perpendicular magnetic anisotropies and variable (reversible) magnetization directions. And magnetizations of FL1 and FL2 are magnetically coupled across the nonmagnetic spacing layer by a dipole coupling. A weak exchange coupling between the FL1 and the FL2 may exist. In absence of external field and absence of spin current, magnetizations of FL1 and FL2 are parallel to each other and substantially perpendicular to a film surface.

### Second Embodiment of Current Invention

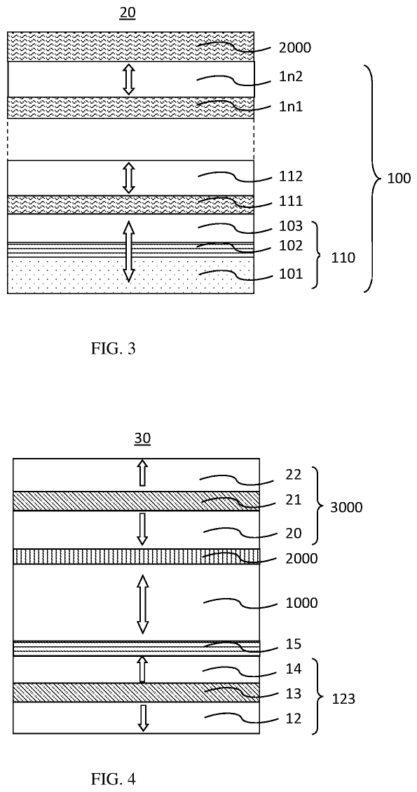

FIG. 3 is a cross-sectional view showing a configuration of a composite recording structure and a cap layer as deposited according to the second embodiment in this invention. The composite recording structure 1000 is configured by stacking a first free layer (FL1) 110, many repeats of a substructure including a nonmagnetic spacing layer and a Co/Ni superlattice free layer, in the order from the bottom to the top. The first free layer consists of an amorphous magnetic material sub-layer 101, a Boron-absorbing material sub-layer 102 atop the amorphous magnetic material sub-layer and a Co/Ni superlattice sub-layer 103 atop the Boron-absorbing material sub-layer. The first substructure consists a first nonmagnetic spacing layer 111 and a second free layer 112, the n-th substructure consists of a n-th nonmagnetic spacing layer 1n1 and a (n+1

)-th free layer 1n2. Further, the cap layer 2000 is provided atop the composite recording structure 1000.

Similar to the first embodiment, the amorphous magnetic material sub-layer 101 is made of CoFeB, CoFeB/Fe, CoB/Fe, CoFe/CoFeB, FeB/CoFe, CoB/CoFe or CoFeB/CoFe. The Boron-absorbing material sub-layer 102 is made of a metal or metal alloy containing at least one element selected from the group of Ta, Hf, Zr, Ti, Mg, Nb, W, Mo, Ru and Al. Both the Co/Ni superlattice sub-layer 103 and all free layers except the first free layer are made of [Co/Ni]n, [Co/Ni]n/Co, [Co/Ni]n/CoFe, Ni/[Co/Ni]n, Ni/[Co/Ni]n/Co or Ni/[Co/Ni]n/CoFe, where n is a positive integer. All nonmagnetic spacing layers and the cap layer are made of a metal or metal alloy of transition metal or transition metal alloy having a face-centered cubic (FCC) crystal structure or a hexagonal close-packed (HCP) crystal structure, such as NiCr, NiFeCr and Ru.

Also as a thermal annealing process is applied to the composite recording structure, Boron elements inside the amorphous magnetic material sub-layer migrate to the Boron-absorbing material sub-layer, and a crystallization process of the amorphous magnetic material sub-layer occurs to form body-centered cubic (bcc) CoFe grains having an epitaxial growth, especially a bcc-CoFe (100)/MgO (100) texture with an underneath MgO tunnel barrier layer. This crystal texture is essential for achieving a high MR ratio. Also after the thermal annealing, the face-centered cubic (FCC) (111) textures of the Co/Ni superlattice sub-layer and all free layers except the first free layer are further improved and leads to perpendicular magnetic anisotropies for all free layers. In another word, all free layers have perpendicular magnetic anisotropies and variable (reversible) magnetization directions. And magnetizations of them are magneto-statically coupled across the nonmagnetic spacing layers by dipole coupling and RKKY coupling. In absence of external field and absence of spin current, magnetizations of all free layers are parallel to each other and substantially perpendicular to a film surface.

### Third Embodiment of Current Invention

FIG. 4 is a cross-sectional view showing an example configuration of a magnetoresistive element 30 as deposited according to the third embodiment. The magnetoresistive element 30 is configured by stacking a reference structure 123, a tunnel barrier layer 15, a composite recording structure 1000, a cap layer 2000 and a magnetic STT-enhancing structure 3000 in the order from the bottom to the top. The reference structure 123 consists of a bottom pinning layer 12, an anti-ferromagnetic coupling (AFC) layer 13 and a reference layer 14. The composite recording structure 1000 consists of a first free layer and many repeats of a substructure including a nonmagnetic spacing layer and a Co/Ni superlattice free layer (not shown here). The magnetic STT-enhancing structure 3000 comprises a first magnetic material layer 20 having a magnetization direction parallel to the magnetization direction of the reference layer, a second AFC coupling layer 21 and a second magnetic material layer 22.

The bottom pinning layer 12 is typically made of super-lattice multilayer and has a strong perpendicular magnetic anisotropy. The bottom pinning layer 12 and the reference layer 14 are magnetically antiparallel-coupled through the anti-ferromagnetic coupling (AFC) layer 13. Each free layer in the composite recording structure has a perpendicular magnetic anisotropy and variable (reversible) magnetization direction, while the reference structure and the magnetic STT-enhancing have invariable (fixing) magnetization directions. The reference structure and the magnetic STT-enhancing structure are synthetic anti-ferromagnetic structures having perpendicular magnetic anisotropic energies which are sufficiently greater than all free layers. In this manner, a spin polarized current may reverse the magnetization direction of each individual free layer while the magnetization directions of the reference structure and the magnetic STT-enhancing structure remains unchanged.

The first magnetic material layer 20 in the magnetic STT-enhancing structure 1002 has a magnetization direction parallel to the magnetization direction of the reference layer 14. The cap layer between the composite recording structure and the magnetic STT-enhancing structure 1002 is a thin nonmagnetic layer having a sufficient large spin diffusion length so that a spin polarized current is able to flow across the cap layer without significant degradation of the spin current polarization. As a spin polarized current is flowing across the magnetoresistive stack, the spin transfer torques coming from the reference layer and the first magnetic material layer are additive, yielding an enhanced spin transfer torque driven reversing power.

An example configuration for the MTJ element 30 is described as follows. The reference structure 123 is made of CoFeB(around 1 nm)/W(around 0.2 nm)/Co(0.5 nm)/Ir(0.4-0.6 nm)/Co(0.5 nm)/[Pt/Co]3/Pt. The tunnel barrier layer 15 is made of MgO (around 1 nm). The composite recording structure 2000 is made of [Co/Ni]n/NiCr(1 nm)/[Co/Ni]n/NiCr(1 nm)/[Co/Ni]n/NiCr(1 nm)/Mo(0.3 nm)/CoFeB(around 1.55 nm) or [Co/Ni]n/NiCr (1 nm)/[Co/Ni]n/NiCr(1 nm)/[Co/Ni]n/NiCr(1 nm)/CoFeB (around 0.6 nm)/Mo(0.3 nm)/CoFeB(around 1.55 nm). The cap layer 19 is made of Ru (around 2.0 nm). The magnetic STT-enhancing structure 1002 is made of Pt/[Co/Pt]3/Co(0.5 nm)/Ir(around 0.4-0.6 nm)/Co(0.5 nm)/W(around 0.2 nm)/CoFeB(around 1 nm).

The thicknesses of Co and Ni of Co/Ni super-lattice in each free layer are arranged such that the free layer has a high spin polarization degree, preferably above 80%. To achieve a high spin polarization degree, each Co sub-layer is about 2 ML (monolayer) thick. The effective perpendicular magnetic anisotropy can be also tunable by controlling the Ni or Co thickness. Doing so, all free layers are tuned to have high spin polarization degrees. The magnetizations of neighbor free layers are magneto-statically coupled across the nonmagnetic spacing layer but individually switchable by sufficiently large spin transfer torques when an electric current is applied in a specific direction.

It is desired that the magnetic anisotropy energy maximum of the first free layer is no more than seventy multiplied by Boltzman's constant multiplied by a temperature of the magnetic junction, and the magnetic anisotropy energy maximum of each Co/Ni super-lattice layer is no more than seventy multiplied by Boltzman's constant multiplied by a temperature of the magnetic junction, however, the sum of magnetic anisotropy energy maximums of the all free layers is more than seventy multiplied by Boltzman's constant multiplied by a temperature of the magnetic junction to maintain a reasonable thermal stability. More specifically, when an electric current is applied in order to write a parallel state into an anti-parallel state, the free layer at the most top experiences the largest spin transfer torque and switches first, then the free layer underneath and at the closest distance to the switched free layer starts to experiences the largest spin transfer torque and switches secondly, etc. On the other hand, when an electric current is applied in order to write an anti-parallel state into a parallel state, the first free layer at the most bottom experiences the largest spin transfer torque and switches first, then the free layer above and at the closest distance to the switched free layer starts to experiences the largest spin transfer torque and switches secondly, etc. As a result, the critical write current at a short pulse is reduced as one free layer would switch first ahead the others, and the switching of magnetization direction propagates to reach all other free layers, while the thermal stability factor of the composite recording structure is essentially a sum of all free layer thermal stability factors and is very high. More importantly, the PMA induced by Co/Ni super-lattices can be tuned to decrease slowly with the temperature than the PMA induced by bcc-CoFe/rocksalt-MgO interface effect, since the PMA induced by Co/Ni is related to the magnetization of Co/Ni super-lattices instead of a stress effect. Preferably, the magnetic anisotropy energy maximum of the first free layer and the magnetic anisotropy energy maximum of each Co/Ni super-lattice layer are roughly the same or have differences less than 30%.

While certain embodiments have been described above, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magnetoresistive element for being used in a magnetic memory device comprising
a composite recording structure comprising:
a first magnetic free layer comprising a first amorphous magnetic material sub-layer, a Boron-absorbing material sub-layer atop the first amorphous magnetic material sub-layer and a Co/Ni superlattice sub-layer atop the Boron-absorbing material sub-layer;
one or many repeats of a substructure including a nonmagnetic spacing layer and a Co/Ni superlattice free layer, atop the first magnetic free layer,
wherein said first magnetic free layer has a perpendicular magnetic anisotropy and a variable magnetization direction substantially perpendicular to a film surface, said each Co/Ni superlattice free layer has a perpendicular magnetic anisotropy and a variable magnetization direction substantially perpendicular to a film surface.

2. The element of claim 1, wherein said first amorphous magnetic material sub-layer comprises at least one ferromagnetic Boron alloy layer selected from the group consisting of CoFeB, CoB and FeB, the B composition percentage is between 10%-35%.

3. The element of claim 1, wherein said Boron-absorbing sub-layer comprises at least one element selected from the group consisting of Ta, Cr, V, Mn, Hf, Zr, Ti, Mg, Nb, W, Mo, Ru and Al, and has a thickness less than 0.4 nm.

4. The element of claim 1, wherein said Co/Ni superlattice sub-layer comprises at least one element selected from the group of [Co/Ni]n, [Co/Ni]n/Co, [Co/Ni]n/CoFe, Ni/[Co/Ni]n, Ni/[Co/Ni]n/Co and Ni/[Co/Ni]n/CoFe, or at least one element selected from the group of (CoFe/Ni), (Co/NiFe), (Co/NiCo), (CoFe/NiFe), and (CoFe/NiCo), wherein CoFe is Co-rich, NiFe and NiCo are Ni-rich.

5. The element of claim 1, wherein each of said nonmagnetic spacing layer is made of a metal or metal alloy of transition metal or transition metal alloy having a face-centered cubic (FCC) crystal structure or a hexagonal close-packed (HCP) crystal structure, preferred to be one of NiCr, NiFeCr, NiCu, Cu, Pt, Pd, Ag, Au and Ru.

6. The element of claim 1, wherein each of said Co/Ni superlattice free layer comprises at least one element selected from the group of [Co/Ni]n, [Co/Ni]n/Co, [Co/Ni]n/CoFe, Ni/[Co/Ni]n, Ni/[Co/Ni]n/Co or Ni/[Co/Ni]n/CoFe, or at least one element selected from the group of (CoFe/Ni), (Co/NiFe), (Co/NiCo), (CoFe/NiFe), and (CoFe/NiCo), wherein CoFe is Co-rich, NiFe and NiCo are Ni-rich.

7. The element of claim 1, further comprising a second amorphous magnetic material sub-layer comprises between said Boron-absorbing material sub-layer and said Co/Ni superlattice sub-layer, wherein said second amorphous magnetic material sub-layer has at least one ferromagnetic Boron alloy layer selected from the group of CoFeB, CoB and FeB, the B composition percentage is between 10%-35%.

8. The element of claim 1, further comprising a tunnel barrier layer directly under said composite recording structure; a magnetic reference layer directly under said tunnel barrier layer; a first anti-ferromagnetic coupling (AFC) layer directly under said magnetic reference layer; a magnetic pinning layer directly under said first AFC layer, and further comprising a seed layer directly under said magnetic pinning layer; a bottom contact layer directly under said seed layer.

9. A method of an improving thermal stability and reducing write consumption of perpendicular spin transfer torque magnetic random access memory (pSTT-MRAM), the method comprising providing a magnetoresistive element comprising:
a substrate;
a bottom contact layer atop the substrate;
a reference structure atop the bottom contact, comprising: a seed layer atop the bottom contact layer; a magnetic pinning layer atop the seed layer; a first anti-ferromagnetic coupling (AFC) layer atop the pinning layer; a magnetic reference layer atop the first AFC layer, wherein the magnetic pinning layer and the magnetic reference layer have perpendicular magnetic anisotropies and invariable magnetization directions, and are antiferromagnetically coupled through the first AFC layer;
a tunnel barrier layer atop the magnetic reference layer;
a recording structure atop the tunnel barrier layer, comprising: a first magnetic free layer comprising an amorphous magnetic material sub-layer, a Boron-absorbing material sub-layer atop the amorphous magnetic material sub-layer and a Co/Ni superlattice sub-layer atop the Boron-absorbing material sub-layer; one or many repeats of a substructure including a nonmagnetic spacing layer and a Co/Ni superlattice free layer, atop the first magnetic free layer, wherein said first magnetic free layer has a perpendicular magnetic anisotropy and a variable magnetization direction substantially perpendicular to a film surface, said each Co/Ni superlattice free layer has a perpendicular magnetic anisotropy and a variable magnetization direction substantially perpendicular to a film surface;
a cap layer atop the recording structure;
a magnetic STT-enhancing structure atop the cap layer, and comprising: a first magnetic material layer and having a perpendicular magnetic anisotropy and an invariable magnetization anti-parallel to the magnetization direction of the reference layer, a second anti-ferromagnetic coupling (AFC) layer atop the first magnetic material layer, and a second magnetic material layer atop the second AFC layer and having a perpendicular magnetic anisotropy and an invariable magnetization in a direction perpendicular to a film surface; and
a top contact layer.

10. The element of claim 9, wherein the tunnel barrier layer consists of one of MgO, MgZnO, MgZrO, MgTiO and MgAlO.

11. The element of claim 9, wherein said first amorphous magnetic material sub-layer comprises at least one ferromagnetic Boron alloy layer selected from the group consisting of CoFeB, CoB and FeB, the B composition percentage is between 10%-35%.

12. The element of claim 9, wherein said Boron-absorbing sub-layer comprises at least one element selected from the group consisting of Ta, Cr, V, Mn, Hf, Zr, Ti, Mg, Nb, W, Mo, Ru and Al, and has a thickness less than 0.4 nm.

13. The element of claim 9, wherein said Co/Ni superlattice sub-layer comprises at least one element selected from the group consisting of [Co/Ni]n, [Co/Ni]n/Co, [Co/Ni]n/CoFe, Ni/[Co/Ni]n, Ni/[Co/Ni]n/Co or Ni/[Co/Ni]n/CoFe, or at least one element selected from the group consisting of (CoFe/Ni), (Co/NiFe), (Co/NiCo), (CoFe/NiFe), and (CoFe/NiCo), wherein CoFe is Co-rich, NiFe and NiCo are Ni-rich.

14. The element of claim 9, wherein each of said nonmagnetic spacing layer is made of a metal or metal alloy of transition metal or transition metal alloy having a face-centered cubic (FCC) crystal structure or a hexagonal close-packed (HCP) crystal structure, preferred to be one of NiCr, NiFeCr and Ru.

15. The element of claim 9, wherein each of said Co/Ni superlattice free layer comprises at least one element selected from the group consisting of [Co/Ni]n, [Co/Ni]n/Co, [Co/Ni]n/CoFe, Ni/[Co/Ni]n, Ni/[Co/Ni]n/Co or Ni/[Co/Ni]n/CoFe, or at least one element selected from the group consisting of (CoFe/Ni), (Co/NiFe), (Co/NiCo), (CoFe/NiFe), and (CoFe/NiCo), wherein CoFe is Co-rich, NiFe and NiCo are Ni-rich.

16. The element of claim 9, wherein said cap layer is made of a metal or metal alloy of transition metal or transition metal alloy having a face-centered cubic (FCC) crystal structure or a hexagonal close-packed (HCP) crystal structure, preferred to be one of NiCr, NiFeCr, NiCu, Cu, Pt, Pd, Ag, Au and Ru, and having a thickness no more than 4 nm.

17. The element of claim 9, further comprising a second amorphous magnetic material sub-layer comprises between said Boron-absorbing material sub-layer and said Co/Ni superlattice sub-layer, wherein said second amorphous magnetic material sub-layer has at least one ferromagnetic Boron alloy layer selected from the group of CoFeB, CoB and FeB, the B composition percentage is between 10%-35%.

18. A magnetoresistive element for being used in a magnetic memory device comprising:
a magnetic reference layer having a perpendicular magnetic anisotropy and an invariable magnetization direction substantially perpendicular to a film surface;
a tunnel barrier layer atop the magnetic reference layer;
a composite recording structure comprising:
a first magnetic free layer atop the tunnel barrier layer and having a perpendicular magnetic anisotropy, a first magnetic anisotropy energy maximum and a variable magnetization direction substantially perpendicular to a film surface;
one or many repeats of a substructure including a spacing layer and a magnetic anisotropy free layer, atop the first magnetic free layer,
wherein said each of magnetic anisotropy free layer has a perpendicular magnetic anisotropy, a magnetic anisotropy energy maximum and a variable magnetization direction substantially perpendicular to a film surface, said each spacing layer is made of a nonmagnetic material and has a sufficiently small thickness so that magnetizations of said first magnetic free layer and said each magnetic anisotropy free layer are magneto-statically coupled and are in a parallel direction substantially perpendicular to a film surface in absent of an external magnetic field and an electric current.

19. The element of claim 18, wherein said first magnetic anisotropy energy maximum of said first magnetic free layer is no more than seventy multiplied by Boltzman's constant multiplied by a temperature of the magnetic junction, said each magnetic anisotropy energy maximum of said each magnetic anisotropy free layer is no more than seventy multiplied by Boltzman's constant multiplied by a temperature of the magnetic junction, and a total sum of said first magnetic anisotropy energy maximum of said first magnetic free layer and said each magnetic anisotropy energy maximum of said each magnetic anisotropy free layer is larger than seventy multiplied by Boltzman's constant multiplied by a temperature of the magnetic junction.

20. The element of claim 18, further comprising:
a cap layer atop said recording structure and comprising a metal layer or an oxide layer;
a magnetic STT-enhancing structure atop the cap layer, and comprising: a first magnetic material layer and having a perpendicular magnetic anisotropy and an invariable magnetization anti-parallel to the magnetization direction of the reference layer, a second anti-ferromagnetic coupling (AFC) layer atop the first magnetic material layer, and a second magnetic material layer atop the second AFC layer and having a perpendicular magnetic anisotropy and an invariable magnetization in a direction substantially perpendicular to a film surface; and
a top contact layer.
